(19) United States
(12) Patent Application Publication
(10) Pub. No.: US 2009/0212309 A1
(43) Pub. Date: Aug. 27, 2009

(54) Light emitting diode package structure and a packaging method thereof

(76) Inventors: Jui-Lun Kuo, Xiushui Shiang (TW); Yao-I Wang, Jhonghe City (TW); Fang-Po Wang, Yonghe City (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 12/071,842

(22) Filed: Feb. 27, 2008

(51) Int. Cl. H01L 33/00

(52) U.S. Cl. 257/98; 438/27; 257/E33.061

(57) ABSTRACT

An LED package structure and an LED packaging method are disclosed. The LED package structure includes a substrate, an LED unit and a transparent holding wall. The LED unit is electrically connected and located on the surface of the substrate. The transparent holding wall that corresponds to the LED unit is formed on the surface of the substrate, and has a receiving space. The LED unit is received in the receiving space. By utilizing the transparent holding wall, the colloid is controllably received in the receiving space and uniformly spread on the surface of the LED unit and around the LED unit. Thereby, the quantity of the colloid is easily controlled, and the LED package structure has a wide lighting angle due to the light emitted from the LED unit can pass through the transparent holding wall.

### BACKGROUND OF THE INVENTION

1. Field of the Invention

The present invention relates to a package structure and a packaging method thereof. In particular, this invention relates to a light emitting diode package structure and a packaging method thereof that forms a transparent holding wall on the surface of the substrate for receiving the colloid so that the colloid is controllable and is uniformly covered the light emitting diode.

2. Description of the Related Art

Reference is made to FIG. 1, which shows a schematic diagram of the light emitting diode (LED) package structure of the prior art. The LED package structure 1a includes a substrate 10a, a phosphor colloid 11a, and an LED 12a. The phosphor colloid 11a and the LED 12a are respectively located on the package surface 100a of the substrate 10a. In the LED packaging method of the prior art, the phosphor colloid 11a is packaged on the LED 12a by using a spot-gluing method to achieve the lighting effect of the LED. However, the spot-gluing process is difficult and the quantity of the phosphor colloid 11a is not easily controlled. Therefore, a high-tech and skilled technology is required. Moreover, the phosphor colloid 11a cannot be uniformly spread on the surface of the LED 12a so that the outline and the color temperature both are not uniform.

Reference is made to FIG. 2, which shows a schematic diagram of another LED package structure 1b of the prior art. The LED package structure 1b includes a main substrate 10a and a posted LED chip 20b. The main substrate 10a has a package surface 100b. The posted LED chip 20b is electrically connected and attached on the package surface 100b by using a heat-melting method. The posted LED chip 20a includes a posted substrate 21b, a receiving cup base 22b located at the edge of the posted substrate 21b, two conducting pins 23b formed at two sides of the posted substrate 21a, a LED 24b located at the surface of the posted substrate 21a and in the receiving cup base 22b, and a phosphor colloid 25b received in the receiving cup base 22b.

However, because the LED package structure 1b needs a posted LED chip 20b, its cost is high. Moreover, because the receiving cup base 22b is not transparent, the generated light is restricted in the receiving cup base 22b so that the lighting angle becomes small. The package structure needs two substrates (such as the main substrate and the posted substrate) so that the heat resistance increases and the heat-conducting efficiency become worse. The lighting efficiency and the usage life of the LED are affected.

Reference is made to FIG. 3, which shows a schematic diagram of a further LED package structure 1c of the prior art. The LED package structure 1c includes a substrate 10c, a phosphor colloid 11c and an LED 12c. The substrate 10c has a package surface 100c and a slot 101c formed on the package surface 100c. The LED 12c is received in the slot 101c and is electrically connected with the substrate 10c by using a flip-chip method. The phosphor colloid 11c is uniformly received in the slot 101c to package the LED 12c. However, because the LED 12c is received in the slot 101c, the lighting angle is restricted by the dimensions of the slot 101c.

### SUMMARY OF THE INVENTION

One particular aspect of the present invention is to provide a light emitting diode package structure and a packaging method thereof that forms a transparent holding wall on the surface of the substrate. A receiving space is formed in the transparent holding wall for receiving the LED. By utilizing the transparent holding wall, the colloid is controllably received in the receiving space and uniformly covered the light emitting diode. Thereby, the color temperature is uniform, and the lighting angle is wide.

The LED package structure includes a substrate, an LED unit, a transparent holding wall, and a colloid. The LED unit is electrically connected and located on the package surface of the substrate. The transparent holding wall is formed on the package surface of the substrate. The LED unit is received in the receiving space of the transparent holding wall. The colloid is controllably received in the receiving space and uniformly spread on the surface of the LED unit and around the LED unit.

The LED packaging method includes the following steps. A molded substrate is provided. A transparent holding wall is formed on the substrate and the transparent holding wall has a receiving space. An LED unit is located in the receiving space of the transparent holding wall and electrically connected with the substrate. A colloid is filled into the receiving space of the transparent holding wall. By utilizing the receiving space, the colloid is controllably and uniformly spread on the surface of the LED unit and around the LED unit.

For further understanding of the invention, reference is made to the following detailed description illustrating the embodiments and examples of the invention. The description is only for illustrating the invention and is not intended to limit of the scope of the claim.

### BRIEF DESCRIPTION OF THE DRAWINGS

The drawings included herein provide a further understanding of the invention. A brief introduction of the drawings is as follows:

FIG. 1 is a schematic diagram of the LED package structure of the prior art;

FIG. 2 is a schematic diagram of another LED package structure of the prior art;

FIG. 3 is a schematic diagram of a further LED package structure of the prior art;

FIG. 4 is a schematic diagram of the LED package structure of the first embodiment of the present invention;

FIG. 5 is a side view of the LED package structure of the first embodiment of the present invention;

FIG. 6 is a schematic diagram of the lighting unit and the transparent holding wall and the LED package structure of the second embodiment of the present invention;

FIG. 7 is a schematic diagram of the lighting unit and the transparent holding wall and the LED package structure of the third embodiment of the present invention;

FIG. 8 is a schematic diagram of the LED packaging method using a pressing device to manufacture the LED package structure of the present invention;

FIG. 9 is a flow chart of the LED packaging method of the present invention; and

FIG. 10 is another flow chart of the LED packaging method of the present invention.

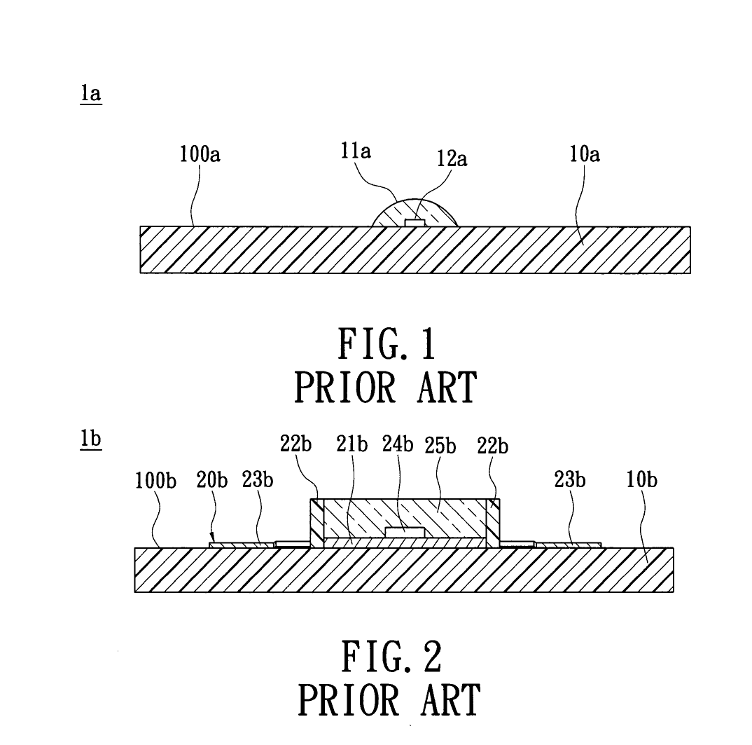

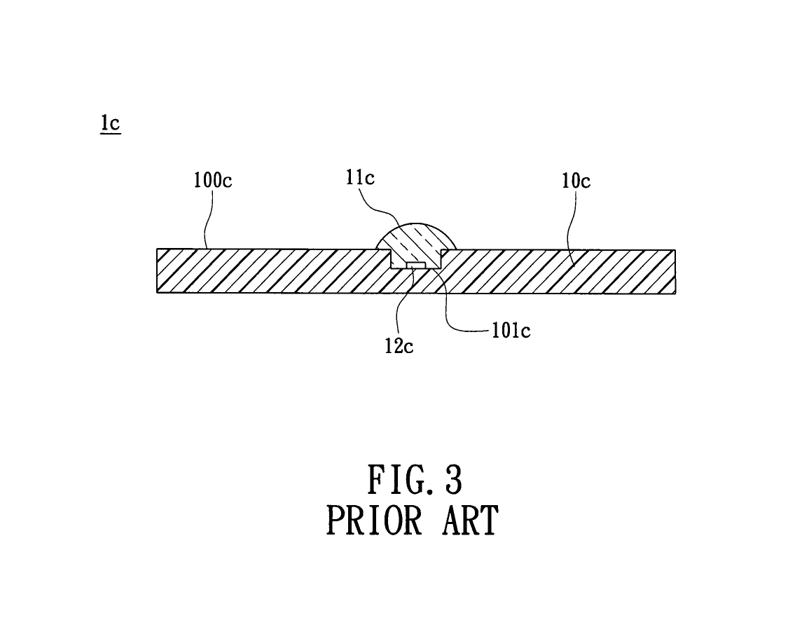

### DETAILED DESCRIPTION OF THE PREFERRED EMBODIMENTS

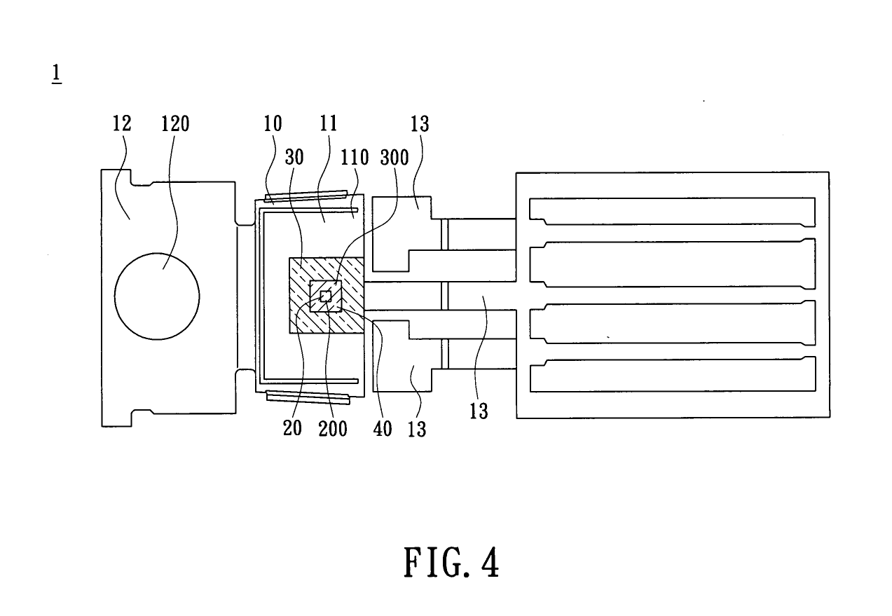

Reference is made to FIGS. 4˜7, which shows the LED package structure of the first embodiment of the present invention. The LED package structure 1 includes a substrate 10, an LED unit 20, a transparent holding wall 30, and a colloid 40.

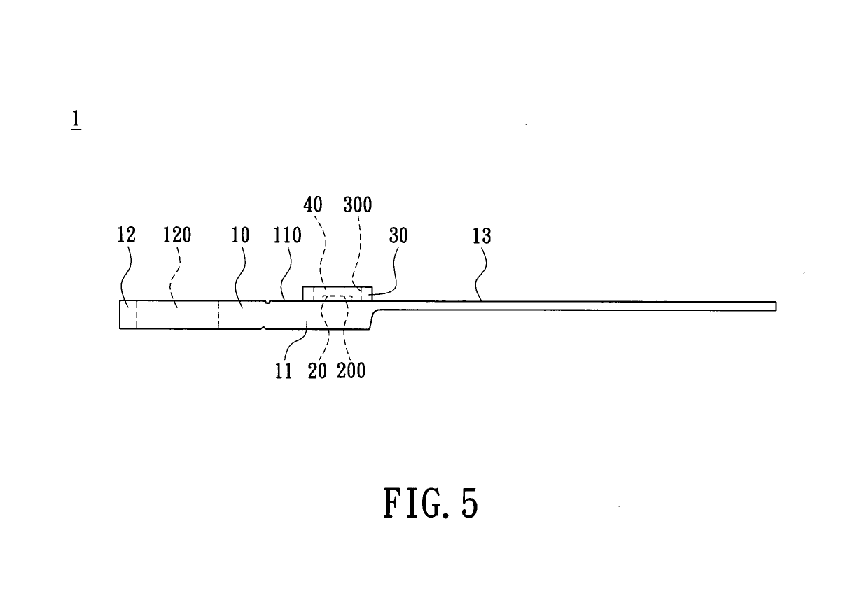

As shown in FIGS. 4 and 5, the substrate 10 is an aluminum substrate, a copper substrate, a silver substrate, or a flexible substrate. In this embodiment, the substrate 10 is a supporting structure for LED and a copper substrate. The substrate 10 has a body portion 11, a top portion 12 and a pin portion 13. The top portion 12 and the pin portion 13 respectively are formed at the two opposing ends of the body portion 1. The body portion 11 has a package surface 110 for receiving the LED unit 20 and the colloid 40. The top portion 12 has a positioning hole 120 for positioning the package. The pin portion 13 is used for being plugged with an external electronic device (not shown in the figure) to electrically connect the electronic device.

The LED unit 20 is electrically connected with the package surface 110 of the body portion 11 of the substrate 10 for generating a lighting source. In this embodiment, the LED unit 20 is one 200 of at least one blue light LED, at least one near-ultraviolet LED, at least one red light LED, or at least one green light LED. Alternatively, the LED unit 20 is a complex LED that is composed of at least one red light LED, at least one green light LED, and at least one blue LED.

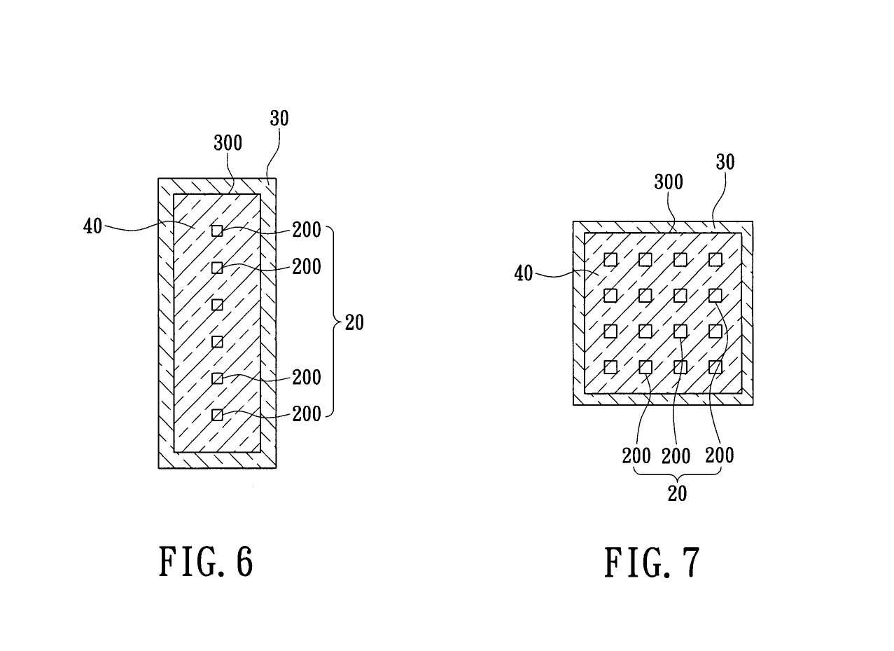

When the LED unit 20 is a blue light LED 200, the colloid 40 is a colloid having yellow phosphor powder, or a colloid having the red phosphor powder and the green phosphor powder. When the LED unit 20 is a near-ultraviolet light LED 200, the colloid 40 is a colloid having the red phosphor powder, the green phosphor powder, and the blue phosphor powder. By cooperating the LED unit 20 and the colloid 40, a white light is lighting. Furthermore, as shown in FIGS. 6 and 7, the LED unit 20 can be a single LED to achieve the point lighting effect, or is composed of a plurality of LEDs 200. The LEDs 200 can be disposed in a pre-determined shape to achieve a strip-shaped lighting effect or a plate-shaped lighting effect. The quantity of the LEDs 200 is not limited to above.

The transparent holding wall 30 is directly formed on the package surface 110 of the body portion 11 of the substrate 10, and the transparent holding wall 30 correspondingly surrounds the LED unit 20. There is a receiving space 300 in the transparent holding wall 30 so that the colloid 40 can be controlled and uniformly cover the LED 200. Thereby, the quantity of the colloid is controlled, and it is easy to perform the packaging operation. The color temperature of the light is uniform.

When the colloid 40 is controllably received in the receiving space 300, the colloid 40 is uniformly spread on the surface of the LED 200, and is firmly fastened on the substrate 10 by utilizing the transparent holding wall 30. Therefore, the LED package structure 1 can be heated immediately so that colloid 40 directly undergoes the hardening procedure in the transparent holding wall 30. The operation time and cost are reduced. Furthermore, because the colloid 40 is uniformly covering the LED unit 20, the light emitted by the LED unit 20 is uniform.

When the hardening procedure is completed, the colloid 40 and the transparent holding wall 30 is a uniform and complete lighting colloid. The light has a uniform color temperature. The problem of the light with a dark area and a bright area is overcome.

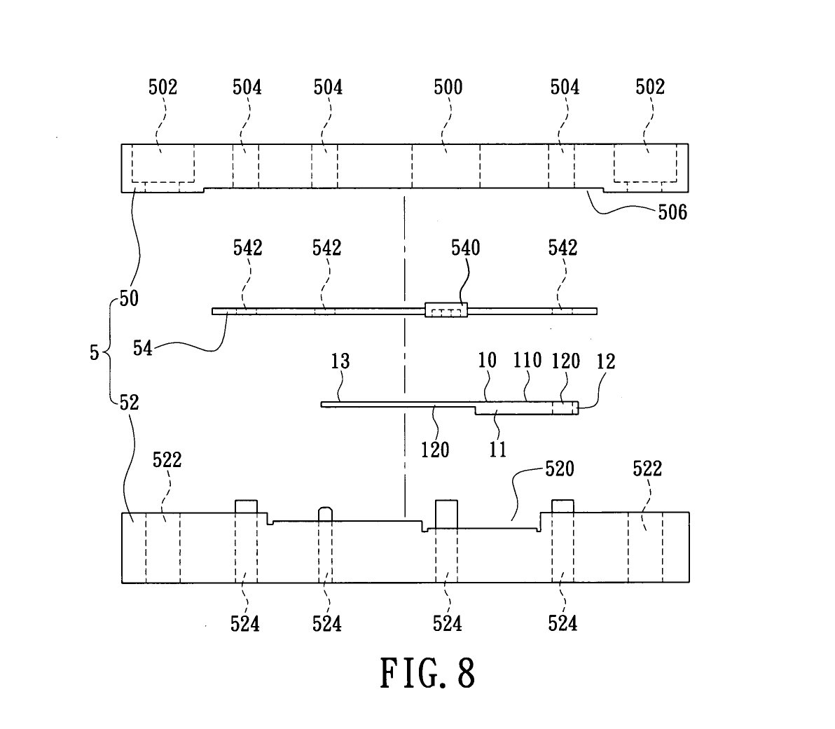

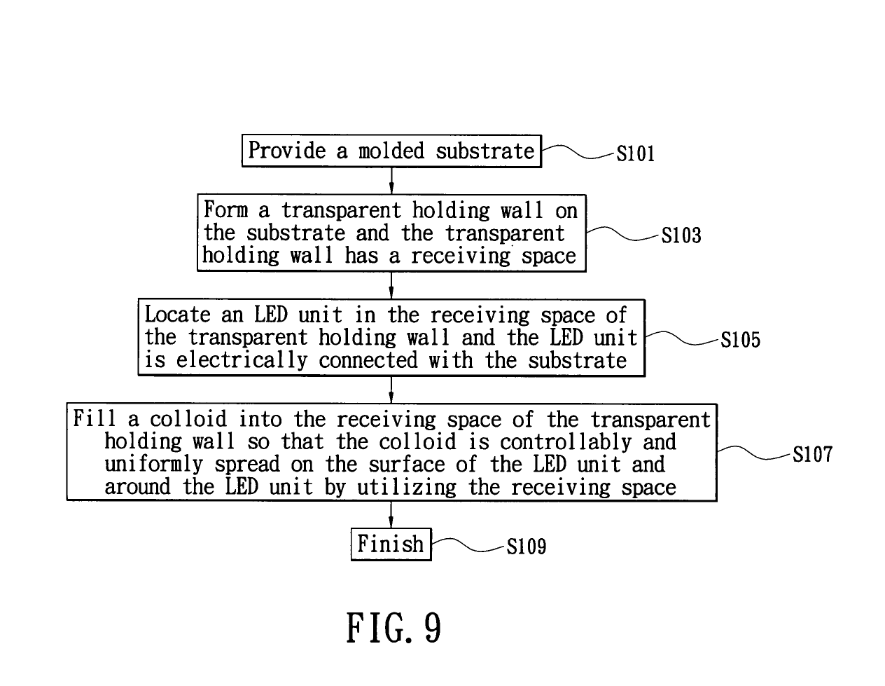

Reference is made to FIGS. 8 and 9, which show a schematic diagram of the LED packaging method using a pressing device to manufacture the LED package structure and a flow chart of the LED packaging method of the present invention. Reference is also made to FIGS. 4 and 5, the LED packaging method includes the following steps.

In the first step, a molded substrate 10 is provided (S101). The substrate 10 is a LED supporting structure, and includes a body portion 11, a top portion 12 and a pin portion 13. The body portion 11 has a package surface 110. The top portion 12 has a positioning hole 120.

In the second step, a transparent holding wall 30 is formed on the substrate 10 and the transparent holding wall 30 has a receiving space 300 (S102). By using a pressing method, a pressing device 5 is pressed on the substrate 10 to form the transparent holding wall 30 onto the substrate 10. In addition to using a mechanical method to press the pressing device 5 onto the substrate 10, the pressing device 5 can be pressed by other pressing methods.

As shown in FIG. 8, in this embodiment, the pressing device 5 includes an upper pressing mold 50, a lower pressing mold 52, and a holding wall forming mold 54. The upper pressing mold 50 and the lower pressing mold 52 matches to each other, and respectively correspond to the package surface 110 of the substrate 10 and a surface that is opposing to the package surface 110. The holding wall forming mold 54 is located between the upper pressing mold 50 and the lower pressing mold 52, and corresponds to the package surface 110 of the substrate 10. By pressing the upper pressing mold 50, the lower pressing mold 52 and the holding wall forming mold 54 of the pressing device 5, the transparent holding wall 30 (as shown in FIG. 4) is formed on the package surface 110 of the substrate 10.

In this embodiment, the upper pressing mold 50 has a colloid-pouring opening 500, two fastening holes 502, three mold flake positioning holes 504, and a first positioning slot 506. The colloid-pouring opening 500 is used for filling the melted colloid (not shown in the figure) into the holding wall forming mold 54, and the holding wall forming mold 54 is correspondingly received in the first positioning slot 506 of the upper pressing mold 50.

The lower pressing mold 52 has a second positioning slot 520 that corresponds to the first positioning slot 506, two fastening portions 522 that respectively correspond to the two fastening holes 502, and four mold flake positioning columns 524. The second positioning slot 520 is used for receiving and positioning the substrate 10. Three of the mold flake positioning columns 524 of the lower pressing mold 52 correspond to the three mold flake positioning holes 504 of the upper pressing mold 50, and one of the mold flake positioning columns 524 corresponds to the colloid-pouring opening 500. Thereby, the upper pressing mold 50 is positioned to the lower pressing mold 52 to perform the pressing operation.

The holding wall forming mold 54 has a forming portion 540 that corresponds to the LED unit 20 (as shown in FIG. 4), and two positioning portions 542. The forming portion 540 is forming structure and is used for forming the transparent holding wall 30 (as shown in FIG. 4) around the LED unit 20. The two positioning portions 542 respectively correspond to the mold flake positioning hole of the upper pressing mold 50 and the mold flake positioning column 504 of the lower pressing mold 52 so that the holding wall forming mold 54 is positioned during the upper pressing mold 50 and the lower pressing mold 52 are pressed. Thereby, the forming portion 540 is exactly formed on the package surface 110 of the body portion 11 of the substrate 10 in the positioned second positioning slot 52.

When the upper pressing mold 50 and the lower pressing mold 52 perform a pressing operation to the holding wall forming mold 54 and the substrate 10, the transparent holding wall 30 is formed on the package surface 110 of the body portion 11 of the substrate 10 by utilizing the forming portion 540 of the holding wall forming mold 54 and using a injection molding method to pour the melted colloid into the colloid-pouring opening 50, and is located around the LED unit 20 (as shown in FIG. 4). The material of the transparent holding wall 30 is transparent or non-transparent so that the transparent holding wall 30 has a transparent and lighting color. After the pressing device 5 is removed, the receiving space 300 is formed in the transparent holding wall 30 for receiving the LED unit 20.

In the third step, an LED unit 20 is located in the receiving space 300 of the transparent holding wall 30 and electrically connected with the substrate 10 (S105). The LED unit 20 includes at least one LED 200 or a plurality of LEDs 200, and is electrically connected with the package surface 110 of the substrate 10 to generate a lighting source.

In the fourth step, a colloid 40 (as shown in FIG. 4) is filled into the receiving space 300 of the transparent holding wall 30. By utilizing the receiving space 300, the colloid 40 is controllably and uniformly spread on the surface of the LED unit 20 and around the LED unit 20 (S107). Finally, the LED package structure is finished (S109).

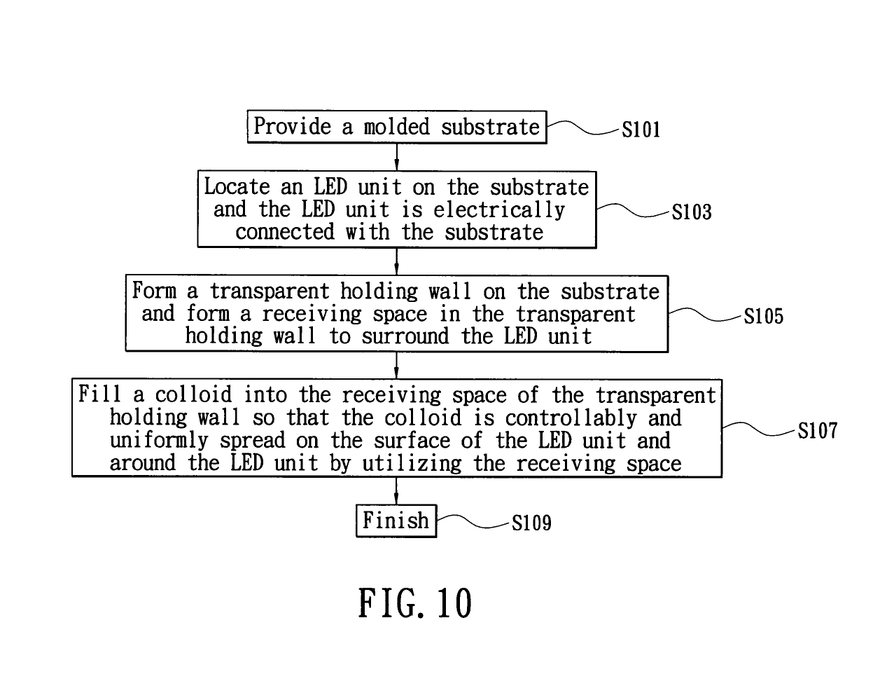

Reference is made to FIG. 10, which shows a flow chart of the LED packaging method of another embodiment of the present invention. The difference between these two embodiments is:

(1) The LED unit 20 is firstly located on the substrate 10. By pressing and removing the pressing device 5, the transparent holding wall 30 is sleeved on the LED unit 20.

(2) The receiving space 300 of the transparent holding wall 30 correspondingly receives the LED unit 20.

Similarly, the colloid 40 is filled to the receiving space 300 and uniformly covers the LED unit 20.

The present invention uses the pressing device to form the transparent holding wall on the surface of the substrate so that the LED package structure has the following characteristics.
1. By utilizing the transparent holding wall, the colloid is controllably received in the receiving space, and uniformly covers the LED so that the color temperature is uniform and the manufacturing time and the cost are reduced.
2. Because the transparent holding wall is pervious to light, the lighting angle is wide after the LED cooperates with the colloid.

The description above only illustrates specific embodiments and examples of the invention. The invention should therefore cover various modifications and variations made to the herein-described structure and operations of the invention, provided they fall within the scope of the invention as defined in the following appended claims.

What is claimed is:

1. An LED package structure, comprising:
a substrate having a package surface;
an LED unit electrically connected and located on the package surface of the substrate;
a transparent holding wall formed on the package surface of the substrate,
wherein the transparent holding wall has a receiving space therein, and the LED unit is received in the receiving space; and
a colloid controllably received in the receiving space and uniformly spread on the surface of the LED unit and around the LED unit.

2. The LED package structure as claimed in claim 1, wherein the LED unit comprises at least one blue light LED.

3. The LED package structure as claimed in claim 2, wherein the colloid is a colloid having yellow phosphor powder.

4. The LED package structure as claimed in claim 2, wherein the colloid is a colloid having red phosphor powder and green phosphor powder.

5. The LED package structure as claimed in claim 1, wherein the LED unit comprises at least one near-ultraviolet LED.

6. The LED package structure as claimed in claim 5, wherein the colloid is a colloid having red phosphor powder, green phosphor powder and blue phosphor powder.

7. The LED package structure as claimed in claim 1, wherein the LED unit comprises at least one red light LED.

8. The LED package structure as claimed in claim 1, wherein the LED unit comprises at least one green light LED.

9. The LED package structure as claimed in claim 1, wherein the LED unit is composed of at least one red light LED, at least one green light LED, and at least one blue light LED.

10. The LED package structure as claimed in claim 1, wherein the substrate is an aluminum substrate, a copper substrate, a silver substrate, or a flexible substrate.

11. An LED packaging method, comprising:
providing a molded substrate;
forming a transparent holding wall on the substrate, wherein the transparent holding wall has a receiving space therein;
locating an LED unit in the receiving space of the transparent holding wall and electrically connecting with the substrate; and
filling a colloid into the receiving space of the transparent holding wall so that the colloid is controllably and uniformly spread on the surface of the LED unit and around the LED unit.

12. The LED packaging method as claimed in claim 11, wherein the LED unit comprises at least one blue light LED.

13. The LED packaging method as claimed in claim 12, wherein the colloid is a colloid having yellow phosphor powder.

14. The LED packaging method as claimed in claim 11, wherein the LED unit comprises at least one red light LED.

15. The LED packaging method as claimed in claim 11, wherein the LED unit comprises at least one green light LED.

16. The LED packaging method as claimed in claim 11, wherein the LED unit is composed of at least one red light LED, at least one green light LED, and at least one blue light LED.

17. The LED packaging method as claimed in claim 11, wherein the substrate is an aluminum substrate, a copper substrate, a silver substrate, or a flexible substrate.

18. The LED packaging method as claimed in claim 11, wherein the transparent holding wall is formed by pressing a pressing device on the substrate, and the receiving space is formed after the pressing device is removed.

19. The LED packaging method as claimed in claim 18, wherein the pressing device comprises an upper pressing mold, a lower pressing mold corresponding to the upper pressing mold and a holding wall forming mold located between the upper pressing mold and the lower pressing mold, the upper pressing mold and the lower pressing mold respectively correspond to an upper surface and a lower surface of the substrate, the holding wall forming mold corresponds to the upper surface of the substrate, and the transparent holding wall is formed by pressing the upper pressing mold, the lower pressing mold and the holding wall forming mold together.

20. The LED packaging method as claimed in claim 19, wherein the holding wall forming mold has a forming portion that corresponds to the LED unit, and the transparent holding wall is correspondingly formed around the LED unit by utilizing the forming portion.
